(19) United States
(12) Patent Application Publication
(10) Pub. No.: US 2022/0413829 A1
(43) Pub. Date: Dec. 29, 2022

(54) OTA UPDATE CONTROL DEVICE AND METHOD FOR VEHICLE

(71) Applicants: Hyundai Motor Company, Seoul (KR); Kia Corporation, Seoul (KR)

(72) Inventor: Min Woo LEE, Suwon-si (KR)

(73) Assignees: Hyundai Motor Company, Seoul (KR); Kia Corporation, Seoul (KR)

(21) Appl. No.: 17/584,616

(22) Filed: Jan. 26, 2022

(30) Foreign Application Priority Data
Jun. 25, 2021 (KR) 10-2021-0083398

(51) Int. Cl. G06F 8/65; B60R 16/023; B60L 58/12

(52) U.S. Cl. CPC G06F 8/65; B60R 16/0231; B60L 58/12; B60L 2270/40; B60L 2240/547

(57) ABSTRACT

An OTA update control device and method for vehicles may include a battery that supplies power to an electric load of the vehicle, a sensor configured for measuring a voltage of the battery, and a controller configured for determining whether to update each ECU based on the voltage of the battery measured whenever each of ECUs provided in the vehicle is updated when the ECUs are updated.

### CROSS-REFERENCE TO RELATED APPLICATION

The present application claims priority to Korean Patent Application No. 10-2021-0083398, filed on Jun. 25, 2021, the entire contents of which is incorporated herein for all purposes by this reference.

### BACKGROUND OF THE INVENTION

### Field of the Invention

The present invention relates to a technology for controlling over-the-air (OTA) update of Electronic Control Units (ECUs) provided in a vehicle.

### Description of Related Art

With the rapid development of electric parts for vehicles, the types and number of electronic devices mounted on vehicles are greatly increasing. The electronic devices may be largely used in a power train control system, a body control system, a chassis control system, a vehicle network, a multimedia system, and the like. The power train control system may include an engine control system, an automatic shift control system, and the like. The body control system may include a body electrical component control system, a convenience device control system, a lamp control system, and the like. A chassis control system may include a steering system control system, a brake control system, a suspension control system, and the like. The vehicle network may include a controller area network (CAN), a FlexRay-based network, a media oriented system transport (MOST)-based network, and the like. The multimedia system may include a navigation system, a telematics system, an infotainment system, and the like.

These systems and electronic devices forming each of the systems are connected through a vehicle network, and a vehicle network for supporting each function of the electronic devices is required. The controller area network (CAN) may support a transmission rate of up to 1 Mbps, and may support automatic retransmission of a collided frame and cycle redundancy check (CRC)-based error detection. The FlexRay-based network may support a transmission rate of up to 10 Mbps, and support simultaneous data transmission through two channels, synchronous data transmission, and the like. The MOST-based network is a communication network for high-quality multimedia and can support a transmission rate of up to 150 Mbps.

On the other hand, a vehicle's telematics system, infotainment system, and improved safety system require high transmission speed and system scalability, and CAN and FlexRay-based networks do not sufficiently support this. A MOST-based network can support a higher transmission rate than a CAN- and FlexRay-based network, but it consumes a lot of cost to apply the MOST-based network to all vehicle networks. Due to these problems, an Ethernet-based network may be considered as a vehicle network. An Ethernet-based network can support bidirectional communication through a pair of windings, and can support transmission rates of up to 10 Gbps.

Recently, the demand for over-the-air (OTA) update of ECUs provided in vehicles is increasing, and accordingly, various methods for updating each ECU connected to the vehicle network have been provided.

The conventional OTA update technology receives update data (background) from the OTA server while driving, and determines whether to update the ECU in consideration of the state of charge (SOC) value of the battery when the engine is stopped (started off). That is, it determines whether or not to update the ECU.

This conventional technique predicts the SOC value of the battery when the engine is stopped without considering the deterioration of the battery, and determines whether to update the ECU based on the predicted SOC value of the battery. Accordingly, in the related art, when the voltage of the battery is rapidly lowered (for example, less than 6V) during the update of the ECU, the update of the ECU is stopped in the middle and the ECU does not operate normally. The related art has a problem in that, when the update of the ECU, which manages engine start-up, is stopped in the middle, the engine start-up becomes impossible.

The information included in this Background of the Invention section is only for enhancement of understanding of the general background of the invention and may not be taken as an acknowledgement or any form of suggestion that this information forms the prior art already known to a person skilled in the art.

### BRIEF SUMMARY

Various aspects of the present invention are directed to providing an OTA update control device and an OTA update control method which measure a voltage of a battery provided in the vehicle whenever each ECU is updated, and determine whether to update a next ECU based on the measured voltage of the battery when sequentially updating a plurality of ECUs provided in the vehicle to prevent update of the ECUs from being suspended due to an error in SOC estimation caused by deterioration of the battery.

The objects of the present invention are not limited to the above-mentioned objects, and other objects and advantages of the present invention which are not mentioned may be understood by the following description, and will be more clearly understood by embodiments of the present invention. It will also be readily apparent that the objects and advantages of the present invention may be realized by the instrumentalities and combinations particularly pointed out in the appended claims

According to various aspects of the present invention, an OTA update control device configured for a vehicle includes a battery that supplies power to an electric load of the vehicle, a sensor configured for measuring a voltage of the battery, and a controller configured for determining whether to update each ECU based on the voltage of the battery measured whenever each of ECUs provided in the vehicle is updated when the ECUs are updated.

According to various exemplary embodiments of the present invention, the controller may perform update of a first ECU among the ECUs when a voltage of the battery measured when updating the first ECU is greater than a reference voltage, perform update of a second ECU among the ECUs when a voltage of the battery measured when updating the second ECU is greater than the reference voltage, and perform no update of a third ECU among the ECUs when a voltage of the battery measured when updating the third ECU is not greater than the reference voltage.

According to various exemplary embodiments of the present invention, the controller may perform a fail-safe function.

According to various exemplary embodiments of the present invention, the controller may restart the update of the ECU and perform roll-back when the update of the ECU is suspended due to a lower voltage of the battery than a predetermined voltage and then, power is normally supplied.

According to various exemplary embodiments of the present invention, a case in which the power is normally supplied may include a case in which the battery is replaced or a case in which the power is supplied from an external battery.

According to various exemplary embodiments of the present invention, the controller may be configured to determine whether to update the ECU when an engine of the vehicle is stopped.

According to various exemplary embodiments of the present invention, the controller may receive update data from an Over The Air (OTA) server when an engine of the vehicle is driven.

According to various aspects of the present invention, an OTA update control method for a vehicle includes measuring, by a sensor, a voltage of a battery provided in the vehicle, and determining, by a controller, whether to update each ECU based on the voltage of the battery measured whenever each of ECUs provided in the vehicle is updated when the ECUs are updated.

According to various exemplary embodiments of the present invention, the determining of whether to update the each ECU may include performing update of a first ECU among the ECUs when a voltage of the battery measured when updating the first ECU is greater than a reference voltage, performing update of a second ECU among the ECUs when a voltage of the battery measured when updating the second ECU is greater than the reference voltage, and performing no update of a third ECU among the ECUs when a voltage of the battery measured when updating the third ECU is not greater than the reference voltage.

According to various exemplary embodiments of the present invention, the OTA update control method may further include performing, by the controller, a fail-safe function.

According to various exemplary embodiments of the present invention, the OTA update control method may further include restarting, by the controller, the update of the ECU and performing roll-back when the update of the ECU is suspended due to a lower voltage of the battery than a predetermined voltage and then, power is normally supplied.

According to various exemplary embodiments of the present invention, the determining of whether to update the each ECU includes determining whether to update the each ECU based on the voltage of the battery when an engine of the vehicle is stopped.

According to various exemplary embodiments of the present invention, the OTA update control method may further include receiving, by the controller, update data from an Over The Air (OTA) server when an engine of the vehicle is driven.

The methods and apparatuses of the present invention have other features and advantages which will be apparent from or are set forth in more detail in the accompanying drawings, which are incorporated herein, and the following Detailed Description, which together serve to explain certain principles of the present invention.

### BRIEF DESCRIPTION OF THE DRAWINGS

FIG. 1 is an exemplary diagram of an OTA update control system for a vehicle to which various exemplary embodiments of the present invention is applied.

FIG. 2 is an exemplary diagram showing a state of a battery provided in an OTA update control system for a vehicle to which various exemplary embodiments of the present invention is applied.

FIG. 3 is a schematic diagram of an OTA update control device configured for a vehicle according to various exemplary embodiments of the present invention.

FIG. 4 is an overall flowchart of an OTA update control method for a vehicle according to various exemplary embodiments of the present invention.

FIG. 5 is a detailed flowchart of an OTA update control method for a vehicle according to various exemplary embodiments of the present invention.

FIG. 6 is a block diagram showing a computing system for executing an OTA update control method for a vehicle according to various exemplary embodiments of the present invention.

It may be understood that the appended drawings are not necessarily to scale, presenting a somewhat simplified representation of various features illustrative of the basic principles of the present invention. The specific design features of the present invention as included herein, including, for example, specific dimensions, orientations, locations, and shapes will be determined in part by the particularly intended application and use environment.

In the figures, reference numbers refer to the same or equivalent parts of the present invention throughout the several figures of the drawing.

### DETAILED DESCRIPTION

Reference will now be made in detail to various embodiments of the present invention(s), examples of which are illustrated in the accompanying drawings and described below. While the present invention(s) will be described in conjunction with exemplary embodiments of the present invention, it will be understood that the present description is not intended to limit the present invention(s) to those exemplary embodiments. On the other hand, the present invention(s) is/are intended to cover not only the exemplary embodiments of the present invention, but also various alternatives, modifications, equivalents and other embodiments, which may be included within the spirit and scope of the present invention as defined by the appended claims.

Hereinafter, various exemplary embodiments of the present invention will be described in detail with reference to the exemplary drawings. In adding the reference numerals to the components of each drawing, it should be noted that the identical or equivalent component is designated by the identical numeral even when they are displayed on other drawings. Furthermore, in describing the exemplary embodiment of the present invention, a detailed description of well-known features or functions will be ruled out in order not to unnecessarily obscure the gist of the present invention.

In describing the components of the exemplary embodiment according to various exemplary embodiments of the present invention, terms such as first, second, “A”, “B”, (a), (b), and the like may be used. These terms are merely intended to distinguish one component from another component, and the terms do not limit the nature, sequence or order of the constituent components. Unless otherwise defined, all terms used herein, including technical or scientific terms, have the same meanings as those generally understood by those skilled in the art to which various exemplary embodiments of the present invention pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

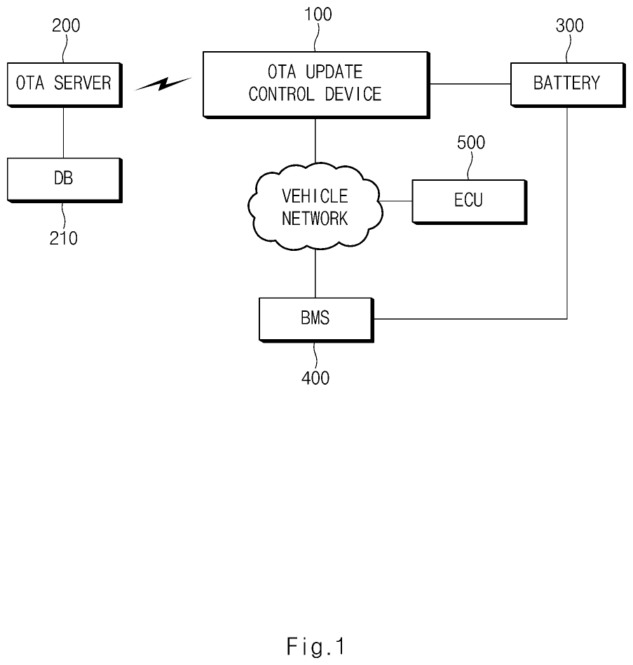

FIG. 1 is an exemplary diagram of an OTA update control system for a vehicle to which various exemplary embodiments of the present invention is applied.

As shown in FIG. 1, an OTA update control system for a vehicle to which various exemplary embodiments of the present invention is applied may include an OTA update control device 100, a server 200, a database (DB) 210, a battery 300, a Battery Management System (BMS), 400, and Electronic Control Units (ECUs) 500.

When sequentially updating a plurality of ECUs provided in the vehicle, the OTA update control device 100 may measure a voltage of a battery provided in the vehicle whenever each ECU is updated, and determine whether to update a next ECU based on the measured voltage of the battery to prevent update of the ECUs from being suspended due to an error in SOC estimation caused by deterioration of the battery.

The OTA server 200 may store and manage update data corresponding to each ECU 500 provided in the vehicle in the database (DB) 210.

The OTA server 200 may manage the update data corresponding to the ID and version information of software stored in the DB 210. In the instant case, the OTA server 200 may store the update data corresponding to the ID and version information of the software in the DB 210.

The OTA server 200 may communicate with the OTA update control device 100 for a vehicle through a wireless communication network. The OTA server 200 may transmit, to the OTA update control device 100, an update table in which the ID and version information of software provided in each ECU 500 of the vehicle are recorded for each version of the vehicle. Also, the OTA server 200 may transmit update data of each ECU 500 provided in the vehicle to the OTA update control device 100.

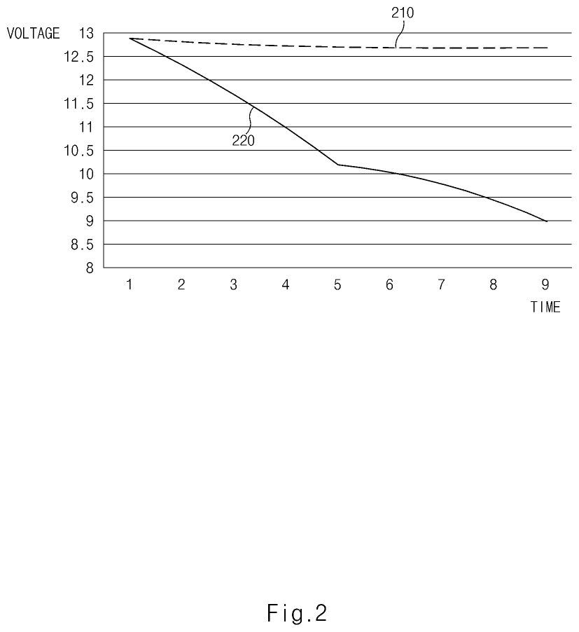

The battery 300 may supply power to an electric load provided in the vehicle. As shown in FIG. 2, the voltage of the battery 300 may vary greatly depending on whether or not the battery deteriorates.

FIG. 2 is an exemplary view showing a state of a battery provided in an OTA update control system for a vehicle to which various exemplary embodiments of the present invention is applied, and shows a voltage transition in a state in which the SOC value of the battery 300 is 90% and 10 A is being discharged.

In FIG. 2, “210” denotes the voltage of the battery 300 in a normal state in which deterioration has not occurred, and “220” denotes the voltage of the battery 300 in which deterioration has occurred. It can be seen in FIG. 2 that, when deterioration has occurred in the battery 300, an initial voltage is the same as 13V, but the voltage rapidly decreases as time passes. Therefore, the SOC value of the battery 300 estimated based on the initial voltage is sufficient to perform the update of the ECU 500, but the voltage suddenly drops in a process of performing the update of the ECU 500 to cause the update of the ECU to be suspended in the middle.

The BMS 400, which is a module for managing the overall state of the battery 300 may estimate the SOC value of the battery 300 and transfer the estimated SOC value of the battery 300 to the OTA update control device 100 through a vehicle network. As various exemplary embodiments of the present invention, the BMS 400 may estimate the SOC value of the battery 300 based on a table representing the relationship between current, voltage, and SOC as shown in Table 1 below.

TABLE 1

| | | | |
|---|---|---|---|
| −5 A | −10 A | −15 A | −20 A |

| | | | | | | | |
|---|---|---|---|---|---|---|---|
| 60% | 10.5 V | 10 | V | 9.5 | V | 9 | V |
| 70% | 10.7 V | 10.2 | V | 9.7 | V | 9.2 | V |
| 80% | 10.9 V | 10.4 | V | 9.9 | V | 9.4 | V |
| 90% | 11.1 V | 10.6 | V | 10.1 | V | 9.6 | V |
| 100% | 11.3 V | 10.8 | V | 10.3 | V | 9.8 | V |

The ECU 500 may be connected to the vehicle network to perform overall control of an engine provided in the vehicle. The ECU 500 may be replaced with a vehicle control unit (VCU) in an electric vehicle and may be replaced with a fuel cell control unit (FCU) in a fuel cell vehicle.

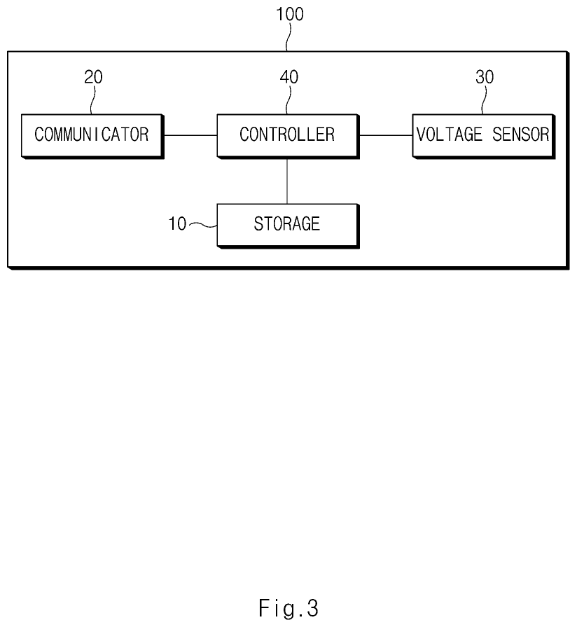

FIG. 3 is a schematic diagram of an OTA update control device for a vehicle according to various exemplary embodiments of the present invention.

As shown in FIG. 3, an OTA update control device for a vehicle according to various exemplary embodiments of the present invention may include storage 10, a communicator 20, a voltage sensor 30, and a controller 40. In the instant case, according to a method for performing the OTA update control device for a vehicle according to various exemplary embodiments of the present invention, components may be combined with each other as one entity, or some components may be omitted.

The components will be described below. First, the storage 10 may store various logics, algorithms, and programs required in a process of measuring a voltage of the battery 300 provided in the vehicle whenever each ECU 500 is updated and determining whether to update a next ECU based on the measured voltage of the battery 300 in the case of sequentially updating a plurality of ECUs 500 provided in the vehicle.

The storage 10 may store various logics, algorithms, and programs required in a process of performing an OTA recovery mode for completing the suspended update of the ECU 500 or performing roll-back when the update of the ECU 500 is suspended and power is then normally supplied again through replacement of the battery 300 or from an external battery. In the instant case, the roll-back may mean returning the software version of the ECU to a software version before the update.

The storage 10 may include at least one type of storage medium of memories such as a flash memory type memory, a hard disk type memory, a micro type memory, and a card type memory (e.g., an Secure Digital card (SC card) or an EXtream Digital card (XD card)), a Random Access Memory (RAM), an Static RAM (SRAM), a Read-Only Memory (ROM), a Programmable ROM (PROM), an Electrically Erasable PROM (EEPROM), a Magnetic RAM (MRAM), a magnetic disk type memory, and an optical disk type memory.

The communicator 20 is a module that provides a communication interface with the OTA server 200, and may download update data (e.g., firmware) to be applied to each ECU 500 from the OTA server 200.

The communicator 20 may include at least one of a mobile communication module, a wireless Internet module, or a short-range communication module.

The mobile communication module may receive update data through a mobile communication network which is established according to a technical standard or a communication scheme for mobile communication (e.g., Global System for Mobile communication (GSM), Code Division Multi Access (CDMA), Code Division Multi Access 2000 (CDMA 2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), or LTE-A (Long Term Evolution-Advanced) and the like.

The wireless Internet module is a module for access to wireless Internet and may receive update data through Wireless LAN (WLAN), Wireless-Fidelity (Wi-Fi), Wi-Fi Direct, Digital Living Network Alliance (DLNA), Wireless Broadband (WiBro), Worldwide Interoperability for Microwave Access (WiMAX), High Speed Downlink Packet Access (HSDPA), High Speed Uplink Packet Access (HSUPA), Long Term Evolution (LTE), Long Term Evolution-Advanced (LTE-A), or the like.

The short-range communication module may support short-range communication using at least one of Bluetooth™, Radio Frequency Identification (RFID), Infrared Data Association (IrDA), Ultra Wideband (UWB), ZigBee, Near Field Communication (NFC), or Wireless USB (Wireless Universal Serial Bus) technology.

The voltage sensor 30 may measure a voltage of the battery 300.

The controller 40 may perform overall control such that each of the above components normally performs its function. The controller 40 may be implemented in a form of hardware or software, or may be implemented in a combination of hardware and software. The controller 40 may be implemented with a microprocessor, but is not limited thereto

The controller 40 may measure a voltage of the battery 300 provided in the vehicle whenever each ECU 500 is updated and perform a variety of control in a process of determining whether to update a next ECU based on the measured voltage of the battery 300 in the case of sequentially updating a plurality of ECUs 500 provided in the vehicle.

Furthermore, the controller 40 may perform a variety of control in a process of performing an OTA recovery mode for restarting the suspended update of the ECU 500 or performing roll-back when the update of the ECU 500 is suspended, and power is then normally supplied again through replacement of the battery 300 or an external battery.

The controller 40 may control the communicator 20 to receive update data from the OTA server 200 while the engine of the vehicle is being driven.

The controller 40 may sequentially update the plurality of ECUs 500 while the engine of the vehicle is stopped. In the instant case, the controller 40 may identify a voltage measured by the voltage sensor 30, when the voltage is greater than a reference value (e.g., 8V), perform update of a first ECU, when the update of the first ECU is completed, identify a voltage measured again by the voltage sensor 30, when the voltage is greater than the reference value (e.g., 8V), perform update of a second ECU, when the update of the second ECU is completed, identify a voltage measured again by the voltage sensor 30, and does not perform an update of a third ECU among the ECUs when the voltage is not greater than the reference value (e.g., 8V). Through the present process, the controller 40 may prevent the update of the ECUs from being suspended.

The controller 40 may further perform a fail-safe function. As described above, when deterioration has occurred in the battery 300, it is difficult to accurately estimate the SOC value of the battery 300. This can also be seen through the voltage transition as shown in FIG. 2. Accordingly, the voltage of the battery 300 exceeds the reference value and the ECU starts to update, but during the ECU update, the voltage of the battery 300 suddenly decreases and the update of the ECU may be stopped. The fail-safe function is a function which is applicable in such a situation.

The controller 40 may perform an OTA recovery mode for restarting the suspended update of the ECU 500 or performing roll-back when the update of the ECU 500 is suspended as the fail-safe function and power is then normally supplied again through replacement of the battery 300 or an external battery. As described above, when power is normally supplied again by replacement of the battery 300 or an external battery, it generally takes 4 hours or more to normally estimate the SOC value of the battery 300. The controller 40 may perform the fail-safe function based on a voltage of the battery 300 without considering the SOC value of the battery 300.

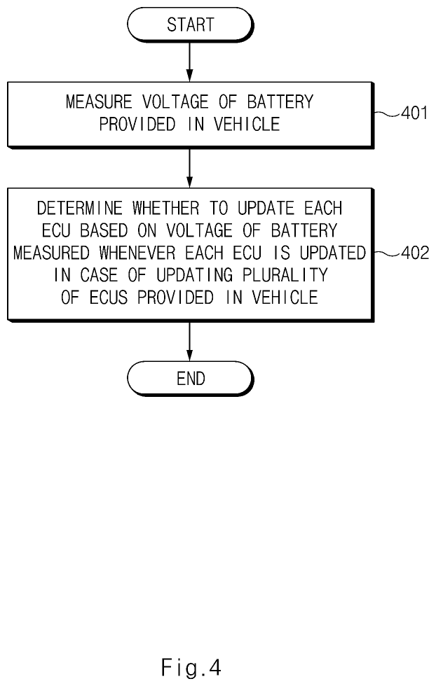

FIG. 4 is an overall flowchart of an OTA update control method for a vehicle according to various exemplary embodiments of the present invention.

First, the voltage sensor 30 may measure a voltage of the battery 300 provided in the vehicle (401).

Thereafter, when the plurality of Electronic Control Units (ECUs) provided in the vehicle are updated, the controller 40 may determine whether to update each ECU based on a voltage of the battery measured whenever each of the ECUs is updated (402).

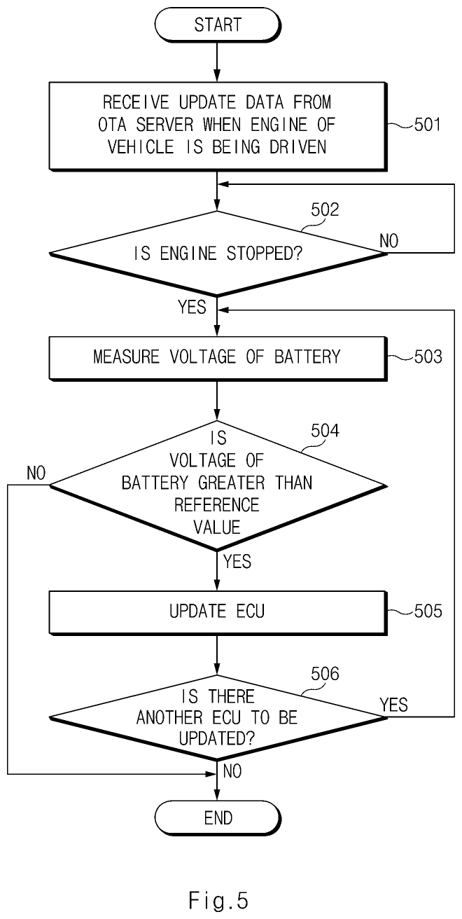

FIG. 5 is a detailed flowchart of an OTA update control method for a vehicle according to various exemplary embodiments of the present invention.

First, the communicator 20 may receive update data from the OTA server 200 while the engine of the vehicle is being driven (501).

Thereafter, the controller 40 may determine whether the engine of the vehicle is stopped (502).

When it is determined that the engine of the vehicle is stopped as a result of the determination (502), the controller 40 may control the voltage sensor 30 to measure a voltage of the battery 300 (503).

Thereafter, the controller 40 may determine whether the voltage of the battery 300 is greater than a reference value (504).

When it is determined that the voltage of the battery 300 is greater than the reference value as a result of the determination (504), the controller 40 may perform the update of an ECU (505).

Thereafter, when there is another ECUs to be updated, the process proceeds to “503”, and when there is no ECU to be updated, the process ends (506).

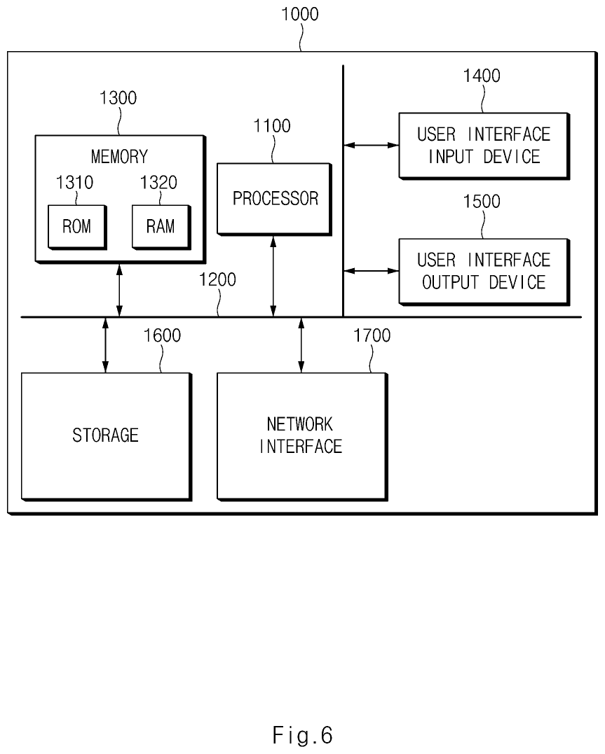

FIG. 6 is a block diagram showing a computing system for executing an OTA update control method for a vehicle according to various exemplary embodiments of the present invention.

Referring to FIG. 6, the OTA update control method for a vehicle according to various exemplary embodiments of the present invention as described above may be also implemented through a computing system. A computing system 1000 may include at least one processor 1100, a memory 1300, a user interface input device 1400, a user interface output device 1500, storage 1600, and a network interface 1700, which are connected to each other via a system bus 1200.

The processor 1100 may be a central processing unit (CPU) or a semiconductor device that processes instructions stored in the memory 1300 and/or the storage 1600. The memory 1300 and the storage 1600 may include various types of volatile or non-volatile storage media. For example, the memory 1300 may include a Read-Only Memory (ROM) 1310 and a Random Access Memory (RAM) 1320.

Thus, the operations of The method or the algorithm described in connection with the exemplary embodiments included herein may be embodied directly in hardware or a software module executed by the processor 1100, or in a combination thereof. The software module may reside on a storage medium (that is, the memory 1300 and/or the storage 1600) such as a RAM, a flash memory, a ROM, an EPROM, an EEPROM, a register, a hard disk, a solid state drive (SSD) a removable disk, and a CD-ROM. The exemplary storage medium may be coupled to the processor 1100, and the processor 1100 may read information out of the storage medium and may record information in the storage medium. Alternatively, the storage medium may be integrated with the processor 1100. The processor and the storage medium may reside in an application specific integrated circuit (ASIC). The ASIC may reside within a user terminal. In another case, the processor and the storage medium may reside in the user terminal as separate components.

The above description is merely illustrative of the technical idea of the present invention, and various modifications and variations may be made without departing from the essential characteristics of the present invention by those skilled in the art to which various exemplary embodiments of the present invention pertains.

Therefore, the exemplary embodiments of the present invention are provided to explain the spirit and scope of the present invention, but not to limit them, so that the spirit and scope of the present invention is not limited by the embodiments. The scope of protection of the present invention should be interpreted by the following claims, and all technical ideas within the scope equivalent thereto should be construed as being included in the scope of the present invention.

According to various exemplary embodiments of the present invention, the OTA update control device and method may measure a voltage of a battery provided in the vehicle whenever each ECU is updated, and determine whether to update a next ECU based on the measured voltage of the battery to prevent update of the ECUs from being suspended due to an error in SOC estimation caused by deterioration of the battery when sequentially updating a plurality of ECUs provided in the vehicle.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The foregoing descriptions of specific exemplary embodiments of the present invention have been presented for purposes of illustration and description. They are not intended to be exhaustive or to limit the present invention to the precise forms disclosed, and obviously many modifications and variations are possible in light of the above teachings. The exemplary embodiments were chosen and described to explain certain principles of the present invention and their practical application, to enable others skilled in the art to make and utilize various exemplary embodiments of the present invention, as well as various alternatives and modifications thereof. It is intended that the scope of the present invention be defined by the Claims appended hereto and their equivalents.

What is claimed is:

1. An Over The Air (OTA) update control apparatus for a vehicle, the apparatus comprising:
a battery configured to supply power to an electric load of the vehicle;
a sensor configured to measure a voltage of the battery; and
a controller configured to determine whether to update each Electronic Control Unit (ECU) based on the voltage of the battery measured whenever each of ECUs provided in the vehicle is updated when the ECUs are updated.

2. The OTA update control apparatus of claim 1, wherein the controller is configured to perform update of a first ECU among the ECUs when a voltage of the battery measured when updating the first ECU is greater than a reference voltage, perform update of a second ECU among the ECUs when a voltage of the battery measured when updating the second ECU is greater than the reference voltage, and perform no update of a third ECU among the ECUs when a voltage of the battery measured when updating the third ECU is not greater than the reference voltage.

3. The OTA update control apparatus of claim 1, wherein the controller is configured to perform a fail-safe function.

4. The OTA update control apparatus of claim 1, wherein the controller is configured to restart the update of the ECU and perform roll-back when the update of the ECU is suspended due to a lower voltage of the battery than a predetermined voltage and then, power is normally supplied.

5. The OTA update control apparatus of claim 3, wherein a case in which the power is normally supplied includes a case in which the battery is replaced or a case in which the power is supplied from an external battery.

6. The OTA update control apparatus of claim 1, wherein the controller is configured to determine whether to update the ECU when an engine of the vehicle is stopped.

7. The OTA update control apparatus of claim 1, wherein the controller is configured to receive update data from an OTA server when an engine of the vehicle is driven.

8. A method of controlling an Over The Air (OTA) update for a vehicle, the method comprising:
measuring, by a sensor, a voltage of a battery provided in the vehicle; and
determining, by a controller, whether to update each Electronic Control Unit (ECU) based on the voltage of the battery measured whenever each of ECUs provided in the vehicle is updated when the ECUs are updated.

9. The method of claim 8, wherein the determining of whether to update the each ECU includes:
performing update of a first ECU among the ECUs when a voltage of the battery measured when updating the first ECU is greater than a reference voltage;
performing update of a second ECU among the ECUs when a voltage of the battery measured when updating the second ECU is greater than the reference voltage; and
performing no update of a third ECU among the ECUs when a voltage of the battery measured when updating the third ECU is not greater than the reference voltage.

10. The method of claim 8, further including:
performing, by the controller, a fail-safe function.

11. The method of claim 8, further including:
restarting, by the controller, the update of the ECU and performing roll-back when the update of the ECU is suspended due to a lower voltage of the battery than a predetermined voltage and then, power is normally supplied.

12. The method of claim 11, wherein a case in which the power is normally supplied includes a case in which the battery is replaced or a case in which the power is supplied from an external battery.

13. The method of claim 8, wherein the determining of whether to update the each ECU includes determining whether to update the each ECU based on the voltage of the battery when an engine of the vehicle is stopped.

14. The method of claim 8, further including:
receiving, by the controller, update data from an OTA server when an engine of the vehicle is driven.
